(19) United States
(12) Patent Application Publication
(10) Pub. No.: US 2025/0167092 A1
(43) Pub. Date: May 22, 2025

(54) ELECTRONIC DEVICE

(71) Applicant: Advanced Semiconductor Engineering, Inc., Kaohsiung (TW)

(72) Inventors: Yung-Li LU, Kaohsiung (TW); Cheng-Nan LIN, Kaohsiung (TW)

(73) Assignee: Advanced Semiconductor Engineering, Inc., Kaohsiung (TW)

(21) Appl. No.: 18/518,322

(22) Filed: Nov. 22, 2023

(51) Int. Cl. H01L 23/498; H01L 23/00; H01L 23/31; H01L 25/00; H01L 25/18

(52) U.S. Cl. CPC H01L 23/49833; H01L 23/3128; H01L 23/49827; H01L 24/13; H01L 24/16; H01L 25/18; H01L 25/50; H01L 24/48; H01L 24/49; H01L 24/73; H01L 2224/13082; H01L 2224/13111; H01L 2224/13124; H01L 2224/13139; H01L 2224/13144; H01L 2224/13147; H01L 2224/13155; H01L 2224/13164; H01L 2224/13184; H01L 2224/16145; H01L 2224/16235; H01L 2224/48091; H01L 2224/48137; H01L 2224/48227; H01L 2224/49109; H01L 2224/73257

(57) ABSTRACT

An electronic device is disclosed. The electronic device includes a first module having a first electronic component, a second module at least partially overlapped with the first module and having an encapsulant, and a first power path penetrating through the encapsulant and providing a first power signal to a backside surface of the first electronic component.

### BACKGROUND

### 1. Field of the Disclosure

The present disclosure generally relates to an electronic device.

### 2. Description of the Related Art

Power path(s) and non-power path(s) are typically provided in the front-end of line (FEOL) or back-end of line (BEOL) of multiple chips or components in a package. Interference between the power signal and the non-power signal can result in power loss and unwanted coupling effect. With the varied characteristics of package structures, such as wafer level packaging, fan-out wafer level packaging, 2.5D/3D IC, etc., the interference problem becomes more complex.

### SUMMARY

In some arrangements, an electronic device includes a first module having a first electronic component, a second module at least partially overlapped with the first module and having an encapsulant, and a first power path penetrating through the encapsulant and providing a first power signal to a backside surface of the first electronic component.

In some arrangements, an electronic device includes a first electronic component having a backside surface, a second electronic component overlapped with the first electronic component and exposing a portion of the backside surface, and a first power path outside of the second electronic component and crossing a lateral surface of the second electronic component. The first power path provides a first power signal to the backside surface of the first electronic component.

In some arrangements, an electronic device includes a first electronic component, a first encapsulant encapsulating the first electronic component, a first conductive element adjacent to the first electronic component and encapsulated by the first encapsulant, and a second electronic component spaced apart from the first encapsulant and covering the conductive element. The second electronic component is configured to receive a power from the first conductive element.

### BRIEF DESCRIPTION OF THE DRAWINGS

Aspects of some arrangements of the present disclosure are readily understood from the following detailed description when read with the accompanying figures. It is noted that various structures may not be drawn to scale, and dimensions of the various structures may be arbitrarily increased or reduced for clarity of discussion.

FIG. 1A illustrates a cross-sectional view of an example of an electronic device according to some arrangements of the present disclosure.

FIG. 1B illustrates a cross-sectional view of an example of an electronic device according to some arrangements of the present disclosure.

FIG. 2 illustrates a cross-sectional view of an example of an electronic device according to some arrangements of the present disclosure.

FIG. 3 illustrates a cross-sectional view of an example of an electronic device according to some arrangements of the present disclosure.

FIG. 4 illustrates a cross-sectional view of an example of an electronic device according to some arrangements of the present disclosure.

FIG. 5 illustrates a cross-sectional view of an example of an electronic device according to some arrangements of the present disclosure.

FIG. 6 illustrates a cross-sectional view of an example of an electronic device according to some arrangements of the present disclosure.

FIGS. 7A, 7B, 7C, 7D, and 7E illustrate cross-sectional views in one or more stages of a method of manufacturing an electronic device in accordance with an arrangement of the present disclosure.

### DETAILED DESCRIPTION

Common reference numerals are used throughout the drawings and the detailed description to indicate the same or similar components. Arrangements of the present disclosure will be readily understood from the following detailed description taken in conjunction with the accompanying drawings.

The following disclosure provides many different arrangements, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include arrangements in which the first and second features are formed or disposed in direct contact, and may also include arrangements in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various arrangements and/or configurations discussed.

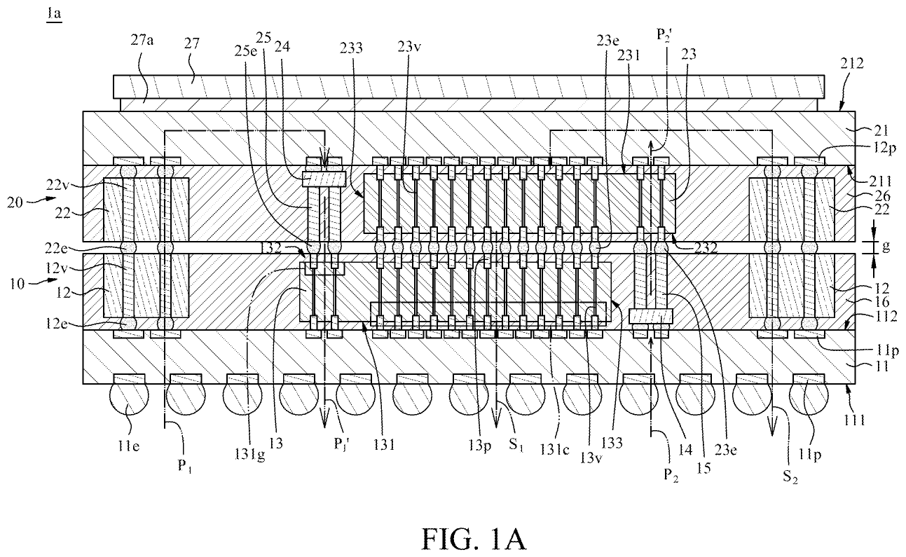

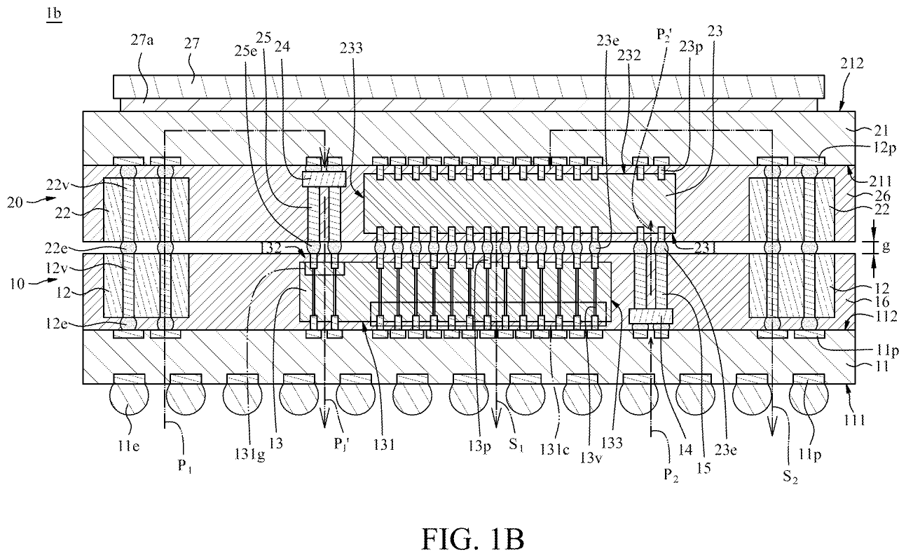

FIG. 1A illustrates a cross-sectional view of an example of an electronic device 1a according to some arrangements of the present disclosure. In some arrangements, the electronic device 1a may include a package, such as a semiconductor device package. In some arrangements, the electronic device 1a may include sub-packages, such as a module 10 and a module 20 disposed over the module 10. The module 10 may be referred to as a first module and the module 20 may be referred to as a second module, or vice versa. The module 10 may be referred to as an upper module and the module 20 may be referred to as a lower module, or vice versa.

The module 10 and the module 20 may be separately formed as unit modules, integrated modules, or monolithic modules, and then may be stacked. The module 10 and the module 20 may be spaced apart (or separated) by a gap “g.” The module 10 and the module 20 may be at least partially overlapped. The module 10 and the module 20 may be electrically connected through electrical contacts 22e, 23e, and 25e. In some arrangements, the electrical contacts 22e, 23e, and 25e may each include a connector. In some arrangements, the electrical contacts 22e, 23e, and 25e may each be disposed within the gap g. In some arrangements, the electrical contacts 22e, 23e, and 25e may each include a solder ball (such as soldering material), such as a controlled collapse chip connection (C4) bump, a ball grid array (BGA), or a land grid array (LGA). In some arrangements, one or more power routing paths (or power paths) and one or more non-power routing paths (or non-power paths) between the module 10 and the module 20 may be transmitted through the electrical contacts 22e, 23e, and/or 25e. In some arrangements, the one or more power routing paths and one or more non-power routing paths between the module 10 and the module 20 may pass through the gap g.

In some arrangements, the module 10 may include a carrier 11, an interconnect structure 12, an electronic component 13, a power regulating device 14, a conductive element 15, and an encapsulating element 16. In some arrangements, the module 20 may include a carrier 21, an interconnect structure 22, an electronic component 23, a power regulating device 24, a conductive element 25, an encapsulating element 26, and a heat dissipating element 27.

In some arrangements, the carrier 11 may include a substrate, such as a semiconductor substrate. In some arrangements, the carrier 11 may include, for example, a printed circuit board (PCB), such as a paper-based copper foil laminate, a composite copper foil laminate, or a polymer-impregnated glass-fiber-based copper foil laminate. The carrier 11 may include a circuit structure or an interconnection structure, such as a redistribution layer (RDL), a circuit layer, a conductive trace, a conductive pad, and a conductive via, etc.

In some arrangements, the carrier 11 may include a surface 111 and a surface 112 opposite to the surface 111. The carrier 11 may include one or more conductive pads 11p in proximity to, adjacent to, or embedded in and exposed by the surface 111 and/or the surface 112 of the carrier 11. The carrier 11 may include a solder resist (not shown) on the surface 111 and/or the surface 112 of the carrier 11 to fully or partially expose the conductive pads 11p for electrical connection, including, for example, the one or more power routing paths and one or more non-power routing paths in the electronic device 1a.

As used herein, a power path may refer to a path dedicated to power supply connections. Additionally, a non-power path may refer to a path through which a non-power signal may be transmitted. Non-power signals may include analog signals, digital signals, clock signals or other electrical signals other than power signals.

In some arrangements, the carrier 11 may provide power and/or grounding connections to the devices or components electrically connected to the carrier 11. For example, the carrier 11 may have a connector or terminal electrically connected to a power source or a power supply (not illustrated in the figures). The carrier 11, the interconnect structure 12, the interconnect structure 22, and the carrier 21 may provide a power path “P₁” between the power supply and the power regulating device 24, which in turn may provide a regulated power signal through a power path “P₁” to the electronic component 13. The carrier 11 may provide a power path “P₂” between the power supply (or another different power supply) and the power regulating device 14, which in turn may provide a regulated power signal through a power path “P₂” to the electronic component 23. In some arrangements, the carrier 11 may serve as a part of the power path P₁, a part of the power path P₁′, and/or a part of the power path P₂.

In some arrangements, the electronic component 13 in the module 10 may receive a power signal (or a regulated power signal) from the power regulating device 24 in the module 20. The electronic component 23 in the module 20 may receive a power signal (or a regulated power signal) from the power regulating device 14 in the module 10. For example, the module 10 and the module 20 are configured to provide a power path to each other. In other words, the module 10 and the module 20 are configured to provide a power signal (or a regulated power signal) to each other.

In some arrangements, the length of the power connection for the electronic component 13 may be different from the length of the power connection for the electronic component 23. For example, the total length of the power path P₁ and the power path P₁′ may be different from the total length of the power path P₂ and the power path P₂′.

In some arrangements, the length of the power connection for the electronic component 13 may be greater than the length of the power connection for the electronic component 23. For example, the total length of the power path P₁ and the power path P₁′ may be greater than (or exceed) the total length of the power path P₂ and the power path P₂′. The total length may be the shortest path of electrical connection. For example, the total length may refer to the most direct route or pathway through which an electrical current can flow from one point to another.

In some arrangements, in a direction substantially perpendicular to the surface 111 and/or the surface 112 of the carrier 11, the power connection for the electronic component 13 and the power connection for the electronic component 23 may be non-overlapped. For example, the power path P₁ and the power path P₁′ may be non-overlapped with the power path P₂ and the power path P₂′. For example, the power path P₁ and the power path P₁′ may pass through the electronic component 13 but not through the electronic component 23. For example, the power path P₂ and the power path P₂′ may pass through the electronic component 23 but not through the electronic component 13.

In some arrangements, an electrical contact 11e may be disposed over the surface 111 of the carrier 11, and can provide non-power connections (or electrical connections) between the electronic device 1a and an external component (e.g., an external circuit or circuit board). In some arrangements, the electrical contact 11e may include a connector. In some arrangements, the electrical contact 11e may be similar to the electrical contacts 22e, 23e, and 25e and may include a solder ball (such as soldering material), such as a C4 bump, a BGA or an LGA.

In some arrangements, the carrier 11 may provide non-power connections to the devices or components electrically connected with the carrier 11. For example, a non-power signal may be transmitted through a non-power path “S₁” between the carrier 11 and the electronic component 13. For example, a non-power signal may be transmitted through a non-power path “S₂” between the carrier 11 and the electronic component 23.

The interconnect structure 12 may be disposed over the surface 112 of the carrier 11. The interconnect structure 12 may include an interposer (such as a substrate interposer or a silicon interposer), an electrical interface, or a fan-out substrate. In some arrangements, the interconnect structure 12 may be configured to spread a connection to a wider pitch or to reroute a connection to a different connection. For example, the interconnect structure 12 may be configured to provide a connection (which may be a power connection or a non-power connection) between the module 10 and the module 20. For example, the interconnect structure 12 may be configured to spread a connection of the carrier 11 to a wider pitch or to reroute a connection of the carrier 11 to a different connection.

In some arrangements, the interconnect structure 12 may include a dielectric layer and one or more conductive elements, such as conductive traces, through vias, redistribution layers (RDLs) or grounding elements. For example, the dielectric layer may include, for example, but is not limited to, one or more organic materials (e.g., a molding compound, bismaleimide triazine (BT), a polyamide (PA), a polyimide (PI), a polybenzoxazole (PBO), a solder resist, an Ajinomoto build-up film (ABF), an epoxy, an epoxy-based material, or a combination of two or more thereof), inorganic materials (e.g., silicon, a glass, a ceramic, a quartz, or a combination of two or more thereof), liquid-film material(s) or dry-film material(s), or a combination of two or more thereof. In some arrangements, the conductive elements may include a conductive via 12v (such as a through via or a through-silicon via (TSV)) and/or a conductive pillar. In some arrangements, the conductive elements may include conductive materials, such as copper (Cu), tin (Sn), aluminum (Al), gold (Au), silver (Ag), tungsten (W), nickel (Ni), palladium (Pd), other suitable materials, or a combination of two or more thereof.

In some arrangements, the interconnect structure 12 may be electrically connected to the interconnect structure 22 of the module 20 through the electrical contact 22e and may be electrically connected to the carrier 11 through an electrical contact 12e (which may be similar to the electrical contact 22e). The electrical contact 22e and the electrical contact 12e may be electrically connected through the conductive via 12v (or another conductive element) of the interconnect structure 12. The electrical contact 22e may be exposed from the encapsulating element 16. The electrical contact 12e may be covered by the encapsulating element 16.

In some arrangements, the interconnect structure 12 of the module 10 and the interconnect structure 22 of the module 20 may be configured to provide, define, construct, or establish one or more power paths (e.g., the power path P₁) and/or one or more non-power paths (e.g., the non-power path S₂) between the module 10 and the module 20.

The module 10 may include two interconnect structures 12 between which the electronic component 13 is disposed. Location and number of the interconnect structure 12 in the module 10 are not intended to limit the present disclosure. For example, there may be any number of interconnect structures on any location in the module 10 due to design requirements.

The electronic component 13 may be disposed over the surface 112 of the carrier 11. The electronic component 13 may be electrically connected to the carrier 11 by way of flip-chip, wire-bond techniques, metal to metal bonding (such as Cu to Cu bonding), or hybrid bonding.

In some arrangements, the electronic component 13 may include an active device. In some arrangements, the electronic component 13 may include circuits or circuit elements that rely on an external power supply to control or modify electrical signals. For example, the electronic component 13 may include a processor, a controller, a memory, or an input/output (I/O) buffer, etc. For example, the electronic component 13 may include a system on chip (SoC). For example, the electronic component 13 may include a central processing unit (CPU), a microprocessor unit (MPU), a graphics processing unit (GPU), a microcontroller unit (MCU), an application-specific integrated circuit (ASIC), a field-programmable gate array (FPGA), or other type of integrated circuit. For example, the electronic component 13 may include a memory, such as a high bandwidth memory (HBM).

In some arrangements, the electronic component 13 may include a surface 131 facing the carrier 11, a surface 132 opposite to the surface 131, and a surface 133 (or a lateral surface, a sidewall, a lateral sidewall) extending between the surface 131 and the surface 132.

In some arrangements, the surface 131 may include an active surface (or a front side) and the surface 132 may include a backside surface (or a rear side). The electronic component 13 may include one or more conductive pads (not annotated) in proximity to, adjacent to, or embedded in and exposed by the surface 131 and/or the surface 132. In some arrangements, the electronic component 13 may include one or more conductive elements 13v. In some arrangements, the conductive element 13v may include a conductive via (such as a through via or a TSV) and/or a conductive pillar. The conductive element 13v may at least partially extend between the surface 131 and the surface 132. The conductive element 13v may electrically connect with the carrier 11. The conductive element 13v may be electrically connected with a logic circuit of the electronic component 13 (such as a non-power circuit 131c in proximity to, adjacent to, or disposed over the surface 131). In some arrangements, one or more conductive elements 13p may be disposed over the backside surface (e.g., the surface 132) of the electronic component 13 and electrically connected with the conductive elements 13v in the electronic component 13.

The location and number of the conductive elements 13v in the electronic component 13 are not intended to limit the present disclosure. For example, there may be any number of the conductive element(s) on any location in the electronic component 13 due to design requirements.

In some arrangements, the electronic component 13 may include the non-power circuit 131c in proximity to, adjacent to, or disposed over the surface 131. In some arrangements, the non-power circuit 131c may include a logic circuit. For example, the non-power circuit 131c may be configured to transmit a non-power signal to the carrier 11 and/or to receive a non-power signal from the carrier 11. For example, the non-power circuit 131c may be configured to perform a logical operation on non-power signals. In some arrangements, the non-power circuit 131c may be electrically connected with the electronic component 23 through the conductive element 13v. Therefore, the non-power circuit 131c may be configured to transmit a non-power signal to the electronic component 23 and/or to receive a non-power signal from the electronic component 23.

In some arrangements, a non-power signal may be transmitted through the non-power path S₁ passing through the non-power circuit 131c. In some arrangements, the non-power path S₁ may be a two-way path. In some arrangements, the non-power path S₁ may support signal transmission for both the electronic component 13 and the electronic component 23. For example, a non-power signal may be transmitted between the electronic component 13 and the carrier 11 through the non-power path S₁. For example, a non-power signal may be transmitted between the electronic component 23 and the carrier 11 through the non-power path S₁.

In some arrangements, a non-power signal may be transmitted through the non-power path S₂ different from the non-power path S₁. The non-power path S₂ may pass through the carrier 21, the interconnect structure 22, the interconnect structure 12, and the carrier 11. The non-power path S₂ may support signal transmission for the electronic component 23. For example, a non-power signal may be transmitted between the electronic component 23 and the carrier 11 through the non-power path S₂.

In some arrangements, a power signal (or a regulated power signal) may be transmitted through the backside surface (e.g., the surface 132) of the electronic component 13. For example, the power path P₁′ may path through the conductive element 25 and enter the backside surface (e.g., the surface 132) of the electronic component 13.

In some arrangements, the electronic component 13 may include a power circuit (or a power delivery circuit, a power delivery network) 131g in proximity to, adjacent to, or disposed over the surface 132. The power circuit 131g may be configured to receive a power signal (or a regulated power signal) from the power regulating device 24 through the power path P₁′. The power circuit 131g may be grounded (or connected to a grounding voltage or a reference voltage) through the carrier 11. The carrier 11 may be configured to provide a grounding voltage or a reference voltage for the power path P₁′.

In some arrangements, the non-power circuit 131c may include a high-speed circuitry region and/or a high-density circuitry region. For example, the circuit density of the non-power circuit 131c may be relatively higher than that of the power circuit 131g. For example, the line spacing and/or the pad pitch of the non-power circuit 131c may be relatively narrower than that of the power circuit 131g.

The power regulating device 14 may be disposed over the surface 112 of the carrier 11. The power regulating device 14 may be electrically connected to the carrier 11 by way of flip-chip, wire-bond techniques, metal to metal bonding (such as Cu to Cu bonding), or hybrid bonding.

In some arrangements, the power regulating device 14 may be configured to receive a power signal through the power path P₂ (e.g., through the carrier 11) and provide a regulated power signal through the power path P₂′ (e.g., through the conductive element 15) to the electronic component 23. In some arrangements, the power regulating device 14 may include a conductive via (such as a through via or a TSV) and/or a conductive pillar for transmitting a regulated power signal through the power path P₂′ (e.g., through the conductive element 15) to the electronic component 23.

In some arrangements, the power regulating device 14 may include a power management integrated circuit (PMIC). In some arrangements, the power regulating device 14 may include a voltage regulator, such as a linear regulator (which is configured to maintain a constant output voltage) or a switching regulator (which is configured to generate an output voltage higher than or lower than the input voltage). In some arrangements, the power regulating device 14 may include a step-down (buck) converter, a step-up (boost) converter, an analog-to-digital converter, a digital-to-analog converter, an AC-DC converter, a DC-DC converter, other types of converters, or a combination thereof.

The conductive element 15 may be disposed over a surface of the power regulating device 14. For example, the conductive element 15 may be disposed over a surface of the power regulating device 14 facing away from the carrier 11. The conductive element 15 may be electrically connected to the power regulating device 14. The conductive element 15 may be electrically connected to the electronic component 23 through the electrical contact 23e. The conductive element 15 may be at least partially exposed from the encapsulating element 16 to contact the electrical contact 23e.

In some arrangements, the conductive element 15 may be configured to provide, define, construct, or establish the power path P₂′ for transmitting a power signal (or a regulated power signal) from the power regulating device 14 to the backside surface (e.g., a surface 232) of the electronic component 23. The power path P₂′ may cross the surface 133 of the electronic component 13. For example, the power path P₂′ may extend between elevations of the surface 131 and the surface 132. The power path P₂′ may be outside of the electronic component 13. The power path P₂′ may not pass through the electronic component 13. The power path P₂′ may pass through the encapsulating element 16. The power path P₂′ may penetrate through the encapsulating element 16.

In some arrangements, the conductive element 15 may include a conductive pillar, a conductive via (such as a through-molding via (TMV)), a conductive trace, a conductive wire, or other feasible connectors. In some arrangements, the conductive element 15 may extend along the surface 133 of the electronic component 13. In some arrangements, the conductive element 15 may be outside of the electronic component 13. In some arrangements, the conductive element 15 may include conductive materials, such as copper (Cu), tin (Sn), aluminum (Al), gold (Au), silver (Ag), tungsten (W), nickel (Ni), palladium (Pd), other suitable materials, or a combination of two or more thereof.

The location and number of the conductive element 15 in the module 10 are not intended to limit the present disclosure. For example, there may be any number of the conductive element(s) on any location in the module 10 due to design requirements.

The encapsulating element 16 may be disposed over the surface 112 of the carrier 11. The encapsulating element 16 may cover, encapsulate, or surround the interconnect structure 12, the electronic component 13, the power regulating device 14, and/or the conductive element 15.

In some arrangements, the encapsulating element 16 may include an encapsulant and/or a molding compound. In some arrangements, the encapsulating element 16 may include a thermosetting polymer, such as an epoxy, a silicone, a polyurethane, a polyimide (PI), a phenolic, or a combination thereof. Suitable fillers may also be included, such as powdered SiO₂.

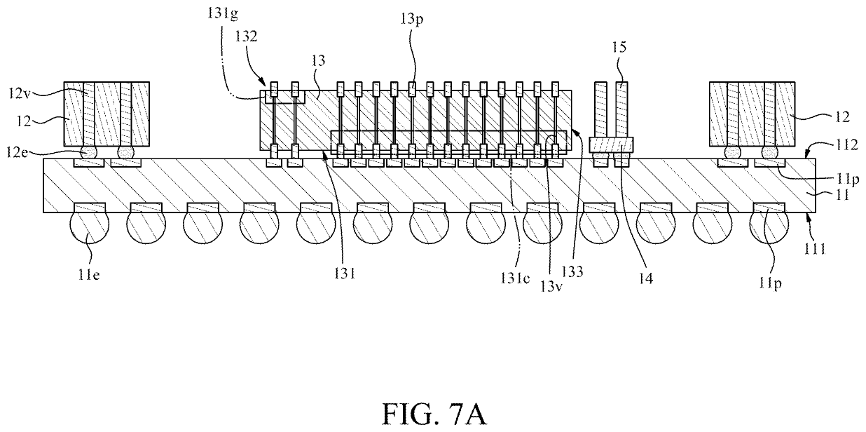

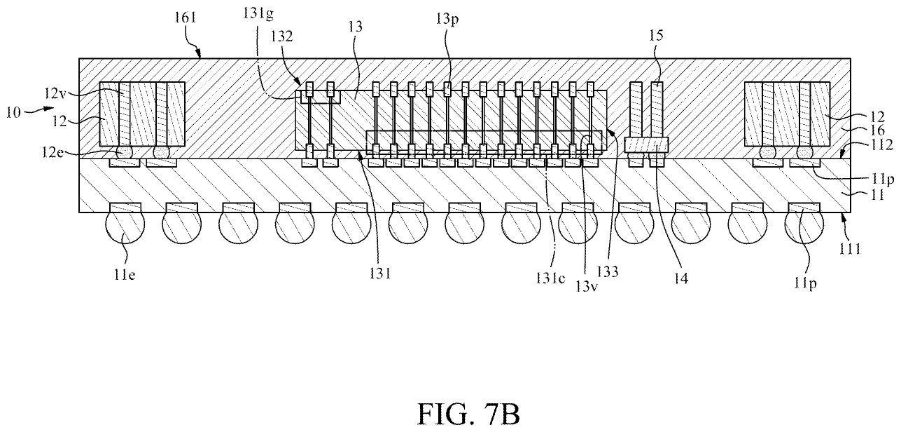

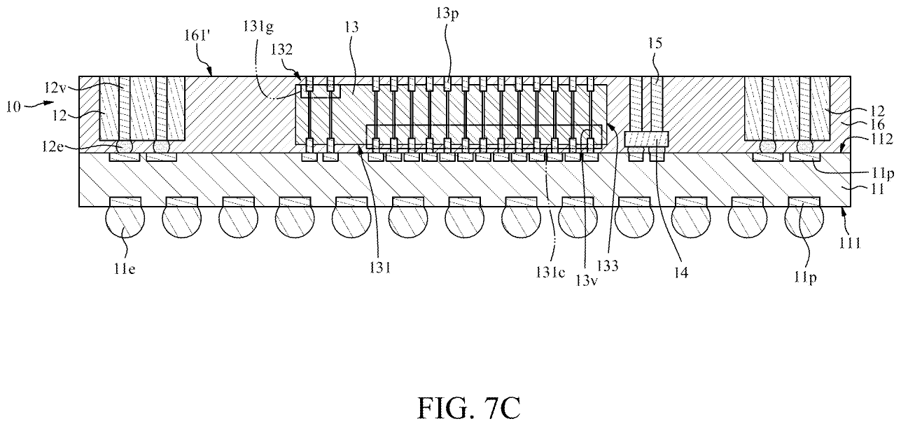

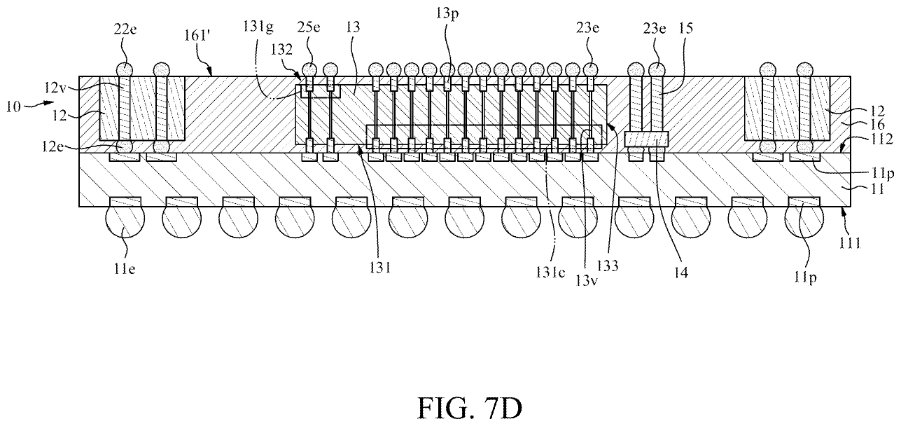

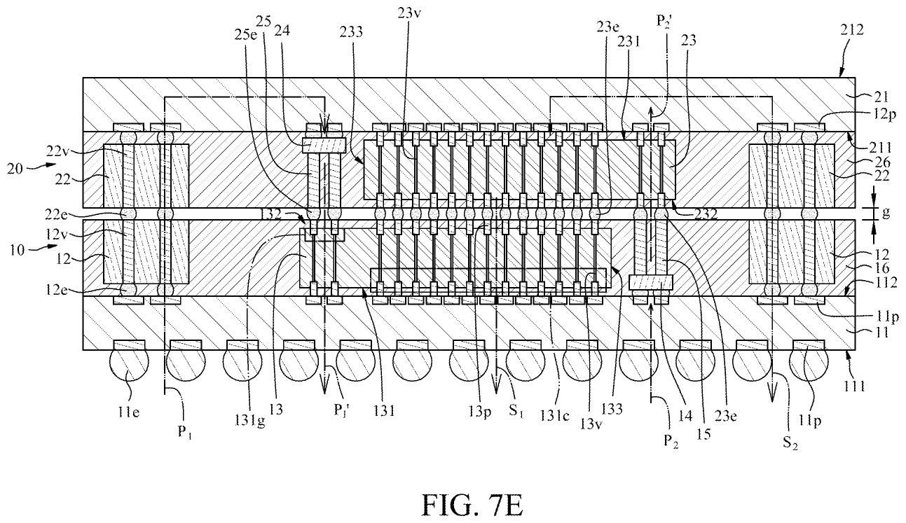

In some arrangements, as shown in FIG. 7B and FIG. 7C, a planarization operation or a grinding operation may be performed to remove at least a portion of the encapsulating element 16. A top surface 161 of the encapsulating element 16 in FIG. 7B may be planarized or ground to a surface 161′ in FIG. 7C. The interconnect structure 12, the conductive pads over the backside surface (e.g., the surface 132) of the electronic component 13, and the conductive element 15 may be exposed by the encapsulating element 16.

The exposed surface of the interconnect structure 12, the exposed surfaces of conductive elements 13p over the backside surface (e.g., the surface 132) of the electronic component 13, the exposed surface of the conductive element 15, and the surface 161′ of the encapsulating element 16 may provide a flat, even, plane, or level surface. The flat surface maintains a consistent height or elevation with respect to the surface 111 and/or the surface 112 of the carrier 11. For example, the upper surface of the encapsulating element 16 may substantially be coplanar with the upper surfaces of conductive elements 13p over the backside surface (e.g., the surface 132) of the electronic component 13, and the upper surface of the conductive element 15.

Therefore, as shown in FIG. 7D and FIG. 7E, the electrical contacts 22e, 23e, and 25e may be disposed over the flat surface and the module 20 may be stacked over the flat surface of the module 10. The production rate and manufacturing yield of the electronic device 1a can be increased.

The carrier 21 may include a surface 211 and a surface 212 opposite to the surface 211. Since the module 20 may be stacked over the flat surface of the module 10, the carrier 21 may maintain a consistent height or elevation with respect to the surface 111 and/or the surface 112 of the carrier 11. In some arrangements, the carrier 21 may serve as a part of the power path P₁ and/or a part of the power path P₂′.

The heat dissipating element 27 may be disposed over the surface 212 of the carrier 21. The heat dissipating element 27 may include a heat sink, such as heat dissipation fins. The heat dissipating element 27 may be configured to provide a heat dissipation path. The heat dissipating element 27 may be configured to dissipate heat to external of the electronic device 1a. In some arrangements, the heat dissipating element 27 may be connected to the surface 212 of the carrier 21 through an adhesive layer 27a, such as a heat dissipation gel.

The interconnect structure 22 may be disposed over the surface 211 of the carrier 21. The location and number of the interconnect structure 22 in the module 20 may correspond to the interconnect structure 12 in the module 10.

The electronic component 23 may be disposed over the surface 211 of the carrier 21. In some arrangements, the electronic component 23 and the electronic component 13 may be overlapped with each other. In some arrangements, the electronic component 23 may expose a portion of the surface 132 of the electronic component 13. In some arrangements, the electronic component 23 and the electronic component 13 may have different functions. For example, the electronic component 23 may include a memory, such as an HBM, providing high bandwidth to the electronic component 13 and increasing the quality and speed of connection. In some arrangements, the electronic component 23 and the electronic component 13 may be electrically connected through the electrical contacts 23e. In some arrangements, the electronic component 23 and the conductive element 15 may be electrically connected through the electrical contacts 23e.

In some arrangements, the electronic component 23 may include a surface 231 facing the carrier 21, a surface 232 opposite to the surface 231, and a surface 233 (or a lateral surface, a sidewall, or a lateral sidewall) extending between the surface 231 and the surface 232. In some arrangements, the surface 231 may include an active surface (or a front side) and the surface 232 may include a backside surface (or a rear side). The electronic component 23 may include one or more conductive pads (not annotated) in proximity to, adjacent to, or embedded in and exposed by the surface 231 and/or the surface 232. In some arrangements, the electronic component 23 may include one or more conductive elements 23v. In some arrangements, the conductive element 23v may include a conductive via (such as a through via or a TSV) and/or a conductive pillar. The conductive element 23v may at least partially extend between the surface 231 and the surface 232. The conductive element 23v may be electrically connected with a logic circuit of the electronic component 23 (such as a non-power circuit in proximity to, adjacent to, or disposed over the surface 231).

In some arrangements, a non-power signal may be transmitted through the non-power path S₂ passing through the active surface (e.g., the surface 231) of the electronic component 23.

In some arrangements, a power signal (or a regulated power signal) may be transmitted through the backside surface (e.g., the surface 232) of the electronic component 23. For example, the power path P₂′ may be transmitted through the conductive element 15 and enter the backside surface (e.g., the surface 232) of the electronic component 23.

In some arrangements, in a direction substantially perpendicular to the surface 111 and/or the surface 112 of the carrier 11, the electronic component 23 and the conductive element 15 may be overlapped. The electronic component 23 and the power regulating device 14 may be overlapped. The conductive element 15 may be disposed between the electronic component 23 and the power regulating device 14.

The power regulating device 24 may be disposed over the surface 211 of the carrier 21. In some arrangements, the power regulating device 24 may be configured to receive a power signal through the power path P₁ (e.g., through carrier 11, the interconnect structure 12, the interconnect structure 22, and the carrier 21) and provide a regulated power signal through the power path P₁′ (e.g., through the conductive element 25) to the electronic component 13.

The conductive element 25 may be disposed over a surface of the power regulating device 24. For example, the conductive element 25 may be disposed over a surface of the power regulating device 24 facing away from the carrier 21. The conductive element 25 may be electrically connected to the power regulating device 24. The conductive element 25 may be electrically connected to the electronic component 13 through the electrical contact 25e. The conductive element 25 may be at least partially exposed from the encapsulating element 26 to contact the electrical contact 25e.

In some arrangements, the conductive element 25 may be configured to provide, define, construct, or establish the power path P₁′ for transmitting a power signal (or a regulated power signal) from the power regulating device 24 to the backside surface (e.g., a surface 132) of the electronic component 13. The power path P₁′ may cross the surface 233 of the electronic component 23. For example, the power path P₁′ may extend between elevations of the surface 231 and the surface 232. The power path P₁′ may be outside of the electronic component 23. The power path P₁′ may not pass through the electronic component 23. The power path P₁′ may pass through the encapsulating element 26. The power path P₁′ may penetrate through the encapsulating element 26.

In some arrangements, in a direction substantially perpendicular to the surface 111 and/or the surface 112 of the carrier 11, the conductive element 25 and the power regulating device 24 may be overlapped with the electronic component 13. The conductive element 25 may be disposed between the electronic component 13 and the power regulating device 24.

The encapsulating element 26 may be disposed over the surface 211 of the carrier 21. The encapsulating element 26 may cover, encapsulate, or surround the interconnect structure 22, the electronic component 23, the power regulating device 24, and/or the conductive element 25.

Detailed descriptions of the carrier 21, the interconnect structure 22, the electronic component 23, the power regulating device 24, the conductive element 25, and the encapsulating element 26 may refer to the corresponding preceding paragraphs of the carrier 11, the interconnect structure 12, the electronic component 13, the power regulating device 14, the conductive element 15, and the encapsulating element 16 and are not repeated hereinafter for conciseness.

In a comparative arrangement, power paths and non-power paths are typically provided in the front-end of line (FEOL) or back-end of line (BEOL) of multiple chips or components in a package. Interference between the power signal and the non-power signal can result in power loss and unnecessary coupling effect. With the varied characteristics of package structure, such as wafer level packaging, fan-out wafer level packaging, 2.5D/3D IC, etc., the interference problem becomes more complex.

According to some arrangements of the present disclosure, by providing the power paths (such as the power paths P₁, P₁′, P₂, and P₂′) outside of the electronic components (such as the electronic components 13 and 23), interference between the power signal and the non-power signal can be reduced. This allows the power signal to be transmitted without using input/output (I/O) pins on active surfaces of the electronic components, freeing up more I/O pins for non-power transmission. As a result, the performance of the electronic components can be improved.

Additionally, stacking and misaligning the electronic components (such as the electronic components 13 and 23) can position the power paths (such as the power paths P₁, P₁′, P₂, and P₂′) outside of the electronic components without increasing the package size. For example, the electronic component 13 of the module 10 and the electronic component 23 of the module 20 are misaligned. The electronic component 13 in the module 10 may receive a regulated power signal from the power regulating device 24 in the module 20 through the power path P₁′. The electronic component 23 in the module 20 may receive a regulated power signal from the power regulating device 14 in the module 10 through the power path P₂′.

Furthermore, integrating the electronic component and the power regulating device into a monolithic module and providing a flat surface can increase production rate and manufacturing yield. For example, the module 10 and the module 20 may be separately formed as unit modules, integrated modules, or monolithic modules. The module 20 may be stacked over the flat surface of the module 10.

FIG. 1B illustrates a cross-sectional view of an example of an electronic device 1b according to some arrangements of the present disclosure. The electronic device 1b is similar to the electronic device 1a in FIG. 1A. Therefore, some detailed descriptions may refer to the corresponding paragraphs above and are not repeated hereinafter for conciseness.

The active surface (e.g., the surface 231) of the electronic component 23 may face away from the carrier 21. The active surface (e.g., the surface 231) of the electronic component 23 may face the backside surface (e.g., the surface 132) of the electronic component 13. In some arrangements, the power path P₂′ may transmit a power signal (or a regulated power signal) from the power regulating device 14 to the active surface (e.g., the surface 231) of the electronic component 23.

The backside surface (e.g., a surface 232) of the electronic component 23 may face the carrier 21. In some arrangements, one or more conductive elements 23p may be disposed over the backside surface (e.g., the surface 232) of the electronic component 23 to provide a heat dissipation path for dissipating heat from the electronic component 23 to the heat dissipating element 27.

In some arrangements, the conductive elements 23p over the backside surface (e.g., the surface 232) of the electronic component 23 in FIG. 1B may be dummy pads.

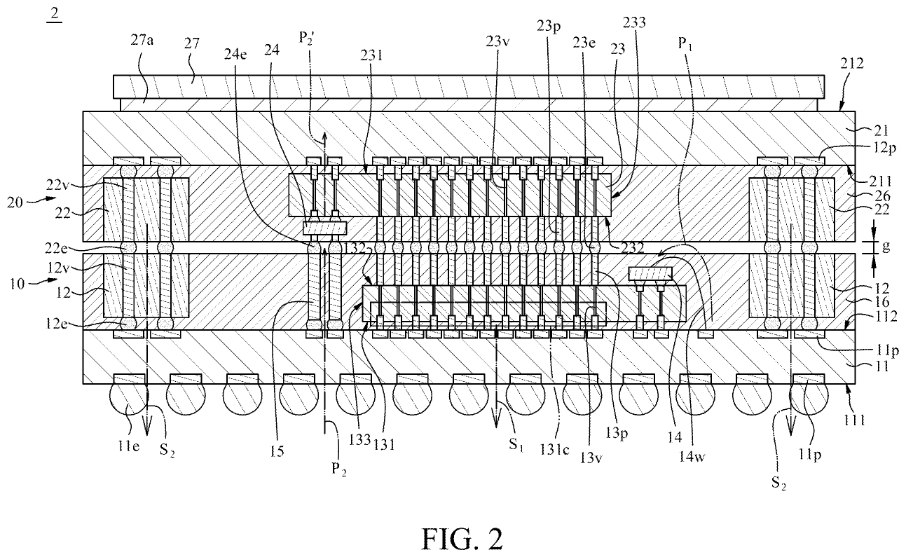

FIG. 2 illustrates a cross-sectional view of an example of an electronic device 2 according to some arrangements of the present disclosure. The electronic device 2 is similar to the electronic device 1a in FIG. 1A. Therefore, some detailed descriptions may refer to the corresponding paragraphs above and are not repeated hereinafter for conciseness.

The module 10 may be configured to provide the power path P₁ to the electronic component 13 in the module 10 and to provide the power path P₂ to the electronic component 23 in the module 20.

The power connection of the electronic component 13 of the module 10 may be provided by the power regulating device 14. The power regulating device 14 may be disposed over the backside surface (e.g., the surface 132) of the electronic component 13. The power regulating device 14 may be electrically connected with the carrier 11 through a conductive wire 14w (or other feasible connectors). The conductive wire 14w may provide the power path P₁ for transmitting a power between a power supply and the power regulating device 14, which in turn may provide a regulated power signal to the electronic component 13.

The power connection of the electronic component 23 of the module 20 may be provided by the power regulating device 24. The power regulating device 24 may be disposed over the backside surface (e.g., the surface 232) of the electronic component 23. The power regulating device 24 may be electrically connected with the carrier 11 through the conductive element 15 and the electrical contact 24e. In some arrangements, the electrical contact 24e may be similar to the electrical contacts 22e, 23e, and 25e and may include a soldering ball, such as a C4 bump, a BGA or an LGA.

The conductive element 15 may provide the power path P₂ for transmitting a power between the power supply (which may be another power supply) and the power regulating device 24, which in turn may provide a regulated power signal to the electronic component 23. In some arrangements, the power regulating device 24 may be disposed between the conductive element 15 and the electronic component 23.

In some arrangements, similar to FIG. 1A, the non-power path S₁ may support signal transmission for both the electronic component 13 and the electronic component 23. In some arrangements, the interconnect structure 12 of the module 10 and the interconnect structure 22 of the module 20 may be configured to provide, define, construct, or establish one or more non-power paths (e.g., the non-power path S₂) between the module 10 and the module 20.

In some arrangements, one or more conductive elements 13p may be disposed over the backside surface (e.g., the surface 132) of the electronic component 13 and electrically connected with the conductive elements 13v in the electronic component 13. The conductive element 13p may include a conductive pillar, a conductive via (such as a TMV), a conductive trace, a conductive wire, or other feasible connectors. In some arrangements, the conductive element 13p may extend from the backside surface (e.g., the surface 132) of the electronic component 13 to an elevation higher than the power regulating device 14 and exposed by the encapsulating element 16.

In some arrangements, one or more conductive elements 23p may be disposed over the backside surface (e.g., the surface 232) of the electronic component 23 and electrically connected with the conductive elements in the electronic component 23. The conductive element 23p may include a conductive pillar, a conductive via (such as a TMV), a conductive trace, a conductive wire, or other feasible connectors. In some arrangements, the conductive element 23p may extend from the backside surface (e.g., the surface 232) of the electronic component 23 to an elevation higher than the power regulating device 24 and exposed by the encapsulating element 26.

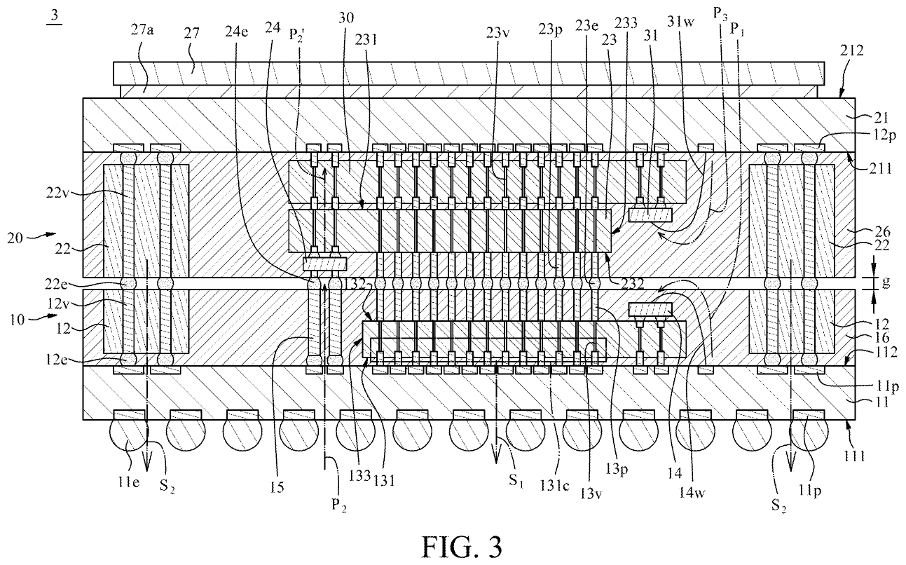

FIG. 3 illustrates a cross-sectional view of an example of an electronic device 3 according to some arrangements of the present disclosure. The electronic device 3 is similar to the electronic device 2 in FIG. 2. Therefore, some detailed descriptions may refer to the corresponding paragraphs above and are not repeated hereinafter for conciseness.

The module 20 of the electronic device 3 further includes an electronic component 30 disposed between the carrier 21 and the electronic component 23. The electronic component 23 may be disposed between the electronic component 30 and the power regulating device 24.

The module 20 of the electronic device 3 further includes a power regulating device 31. The power connection of the electronic component 30 of the module 20 may be provided by the power regulating device 31. The power regulating device 31 may be disposed over the backside surface of the electronic component 30. The power regulating device 31 may be electrically connected with the carrier 21 through a conductive wire 31w (or other feasible connectors). The conductive wire 31w may provide a power path P₃ for transmitting a power between a power supply and the power regulating device 31, which in turn may provide a regulated power signal to the electronic component 30.

Detailed descriptions of the electronic component 30 and the power regulating device 31 may refer to the corresponding preceding paragraphs of the electronic component 13 and the power regulating device 14, and are not repeated hereinafter for conciseness.

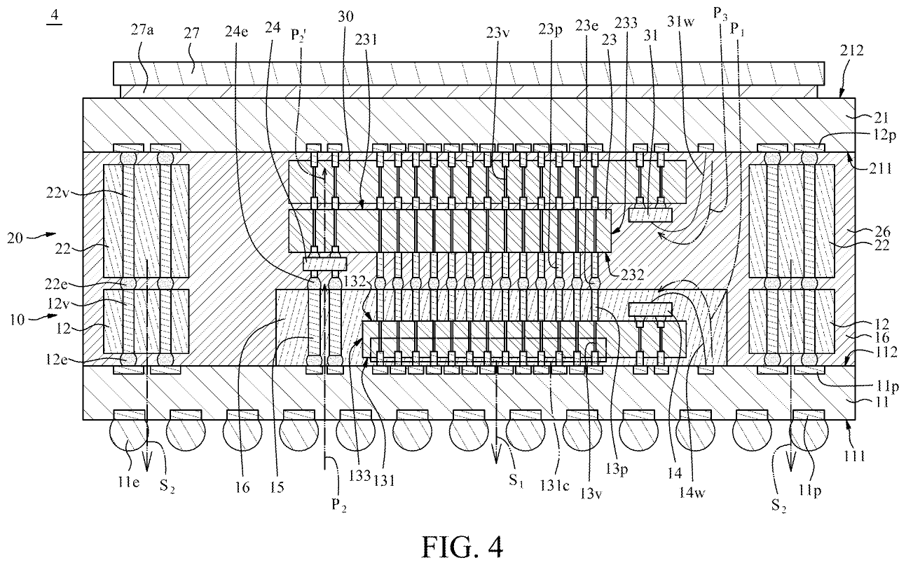

FIG. 4 illustrates a cross-sectional view of an example of an electronic device 4 according to some arrangements of the present disclosure. The electronic device 4 is similar to the electronic device 3 in FIG. 3. Therefore, some detailed descriptions may refer to the corresponding paragraphs above and are not repeated hereinafter for conciseness.

The encapsulating element 16 may cover, encapsulate, or surround the electronic component 13, the power regulating device 14, and/or the conductive element 15. The interconnect structure 12 may be covered, encapsulated, or surrounded by the encapsulating element 26. The encapsulating element 26 may be disposed over the surface 112 of the carrier 11. The encapsulating element 26 may contact the surface 112 of the carrier 11.

In some arrangements, the module 10 (including the electronic component 13, the power regulating device 14, the conductive element 15, and the encapsulating element 16) may be covered, encapsulated, or surrounded by the encapsulating element 26. In some arrangements, the module 10 may be covered, encapsulated, or surrounded by the encapsulating element 26 of the module 20. In some arrangements, since the module 10 and the module 20 are connected or attached to each other by the encapsulating element 26, the electrical contacts 22e, 23e, and 24e may be covered, encapsulated, or surrounded by the encapsulating element 26 of the module 20. The coefficient of thermal expansion (CTE) mismatch may be reduced and the reliability of the electronic device 4 may be improved.

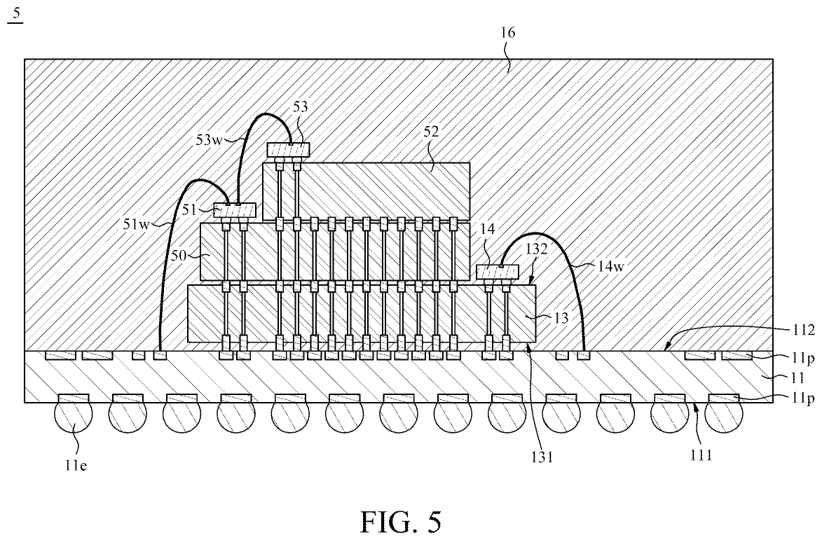

FIG. 5 illustrates a cross-sectional view of an example of an electronic device 5 according to some arrangements of the present disclosure. The electronic device 5 is similar to the module 10 of the electronic device 1a in FIG. 1A. Therefore, some detailed descriptions may refer to the corresponding paragraphs above and are not repeated hereinafter for conciseness.

The power regulating device 14 may be disposed over the backside surface (e.g., the surface 132) of the electronic component 13. The power regulating device 14 may be electrically connected with the carrier 11 through a conductive wire 14w (or other feasible connectors). The conductive wire 14w may provide a power path for transmitting a power between a power supply and the power regulating device 14, which in turn may provide a regulated power signal to the electronic component 13.

An electronic component 50 may be disposed over the backside surface (e.g., the surface 132) of the electronic component 13. A power regulating device 51 may be disposed over the backside surface of the electronic component 50 and electrically connected with the carrier 11 through a conductive wire 51w. The conductive wire 51w may provide a power path for transmitting a power between a power supply and the power regulating device 51, which in turn may provide a regulated power signal to the electronic component 50.

An electronic component 52 may be disposed over the backside surface of the electronic component 50. A power regulating device 53 may be disposed over the backside surface of the electronic component 52 and electrically connected with the power regulating device 51 through a conductive wire 53w. The conductive wire 53w may provide a power path for transmitting a power between the power regulating device 51 and the power regulating device 53, which in turn may provide a regulated power signal to the electronic component 52.

In some arrangements, the power regulating device 51 may function as a relay station of the power connection between the carrier 11 and the power regulating device 53. For example, the power regulating device 51 may not use or alter the power connection between the carrier 11 and the power regulating device 53. By connecting the power regulating device 53 to the power regulating device 51 through the conductive wire 53w, the wire length may be less than connecting the power regulating device 53 to the carrier 11. Therefore, the risk of wires being crushed during molding can be reduced.

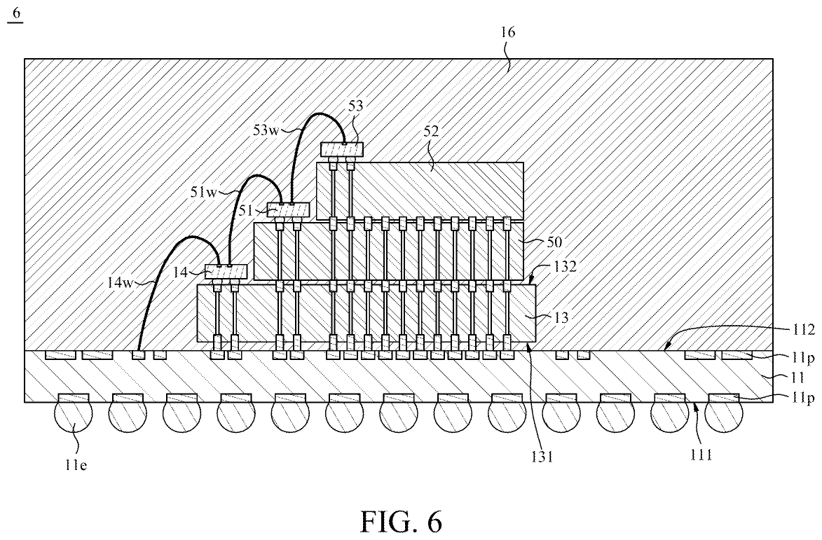

FIG. 6 illustrates a cross-sectional view of an example of an electronic device 6 according to some arrangements of the present disclosure. The electronic device 6 is similar to the module 10 of the electronic device 1a in FIG. 1A and the electronic device 5 in FIG. 5. Therefore, some detailed descriptions may refer to the corresponding paragraphs above and are not repeated hereinafter for conciseness.

The power regulating device 51 may be disposed over the backside surface of the electronic component 50 and electrically connected with the power regulating device 14 through the conductive wire 51w. The conductive wire 51w may provide a power path for transmitting a power between the power regulating device 14 and the power regulating device 51, which in turn may provide a regulated power signal to the electronic component 50.

In some arrangements, the power regulating device 14 may function as a relay station of the power connection between the carrier 11 and the power regulating device 51. For example, the power regulating device 14 may not use or alter the power connection between the carrier 11 and the power regulating device 51. By connecting the power regulating device 51 to the power regulating device 14 through the conductive wire 51w, the wire length may be less than connecting the power regulating device 51 to the carrier 11. Therefore, the risk of wires being crushed during molding can be reduced.

FIGS. 7A, 7B, 7C, 7D, and 7E illustrate cross-sectional views in one or more stages of a method of manufacturing an electronic device in accordance with an arrangement of the present disclosure. At least some of these figures have been simplified to better understand the aspects of the present disclosure. In some arrangements, a part of the electronic device 1a may be manufactured through the operations described with respect to FIGS. 7A, 7B, 7C, 7D, and 7E.

Referring to FIG. 7A, a carrier may be provided. In some arrangements, the carrier may include several units (such as the carrier 11) which may be separable from each other by a scribe line (not shown). Each carrier 11 may have the surface 111 and the surface 112 opposite to the surface 111. Since each carrier 11 is subjected to similar or identical processes in the manufacturing method, for convenience, only one exemplary carrier 11 is illustrated and described in the following description.

The interconnect structure 12, the electronic component 13, the power regulating device 14, and the conductive element 15 may be disposed over the carrier 11.

Referring to FIG. 7B, the encapsulating element 16 may be disposed over the surface 112 of the carrier 11 to cover, encapsulate, or surround the interconnect structure 12, the electronic component 13, the power regulating device 14, and the conductive element 15. In some arrangements, the encapsulating element 16 may be formed by printing, compressive molding, transfer molding, liquid encapsulant molding, vacuum lamination, spin coating, or other suitable processes. In some arrangements, the encapsulating element 16 may have a top surface 161 facing away from the carrier 11.

Referring to FIG. 7C, a planarization operation or a grinding operation may be performed to remove at least a portion of the encapsulating element 16. The top surface 161 of the encapsulating element 16 in FIG. 7B may be planarized or ground to a surface 161′. The interconnect structure 12, the conductive pads over the backside surface (e.g., the surface 132) of the electronic component 13, and the conductive element 15 may be exposed by the encapsulating element 16. The surface 161′ may be a flat, even, plane, or level surface. The surface 161′ may maintain a consistent height or elevation with respect to the surface 111 and/or the surface 112 of the carrier 11. The structure obtained from the operation in FIG. 7C may be similar to the module 10 in FIG. 1A.

The planarization operation or grinding operation may include an abrasive machining process that uses a grinding wheel or grinder, a chemical mechanical planarization (CMP) process, an etching process, or a laser direct ablation (LDA) process.

Referring to FIG. 7D, the electrical contacts 22e, 23e, and 25e may be disposed in proximity to, adjacent to, or disposed over the surface 161′. Singulation may be performed to separate out individual electronic components (or unit chips). The singulation may be performed, for example, by using a dicing saw, laser, or other appropriate cutting technique.

Referring to FIG. 7E, the module 20 may be electrically connected to the module 10 through the electrical contacts 22e, 23e, and 25e. The module 20 may be manufactured by processes similar to the module 10. The obtained structure may be similar to the electronic device 1a in FIG. 1A.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to #1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a first module having a first electronic component;
a second module at least partially overlapped with the first module and having an encapsulant; and
a first power path penetrating through the encapsulant and providing a first power signal to a backside surface of the first electronic component.

2. The electronic device of claim 1, wherein the second module further comprises a second electronic component covered by the encapsulant, and the first power path is outside of the second electronic component.

3. The electronic device of claim 2, wherein the second electronic component and the first power path are non-overlapped.

4. The electronic device of claim 2, further comprising:
a second power path at least partially within the first module and configured to provide a second power signal to a backside surface of the second electronic component.

5. The electronic device of claim 4, wherein the first electronic component and the second power path are non-overlapped.

6. The electronic device of claim 4, wherein the second power path is outside of the first electronic component.

7. The electronic device of claim 4, wherein the first module further comprises a first carrier over which the first electronic component is disposed, and wherein the first carrier serves as a part of the first power path and a part of the second power path.

8. The electronic device of claim 7, wherein the second module further comprises a second carrier over which the encapsulant is disposed, wherein the second carrier serves as a part of the first power path.

9. The electronic device of claim 1, wherein the first electronic component has a power circuit adjacent to the backside surface and configured to receive the first power signal through the first power path.

10. The electronic device of claim 1, wherein the first module further comprises an encapsulant spaced apart from the encapsulant of the second module, and the electronic device further comprises:
a second power path penetrating through the encapsulant of the first module and provide a second power signal to a backside surface of a second electronic component of the second module.

11. The electronic device of claim 10, wherein a length of the second power path is greater than a length of the first power path.

12. The electronic device of claim 1, wherein the first module further comprises a power regulating device disposed over the backside surface of the first electronic component.

13. The electronic device of claim 12, wherein the second module further comprises a conductive element partially exposed from the encapsulant and electrically connected with the power regulating device.

14. The electronic device of claim 1, wherein the first module further comprises an encapsulant covering the encapsulant of the second module.

15. An electronic device, comprising:
a first electronic component having a backside surface;
a second electronic component overlapped with the first electronic component and exposing a portion of the backside surface; and
a first power path outside of the second electronic component and crossing a lateral surface of the second electronic component,
wherein the first power path provides a first power signal to the backside surface of the first electronic component.

16. The electronic device of claim 15, wherein a backside surface of the second electronic component faces the backside surface of the first electronic component.

17. The electronic device of claim 16, wherein a second power path outside of the first electronic component and crossing a lateral surface of the first electronic component and provide a second power signal to the backside surface of the second electronic component.

18. An electronic device, comprising:
a first electronic component;
a first encapsulant encapsulating the first electronic component;
a first conductive element adjacent to the first electronic component and encapsulated by the first encapsulant; and
a second electronic component spaced apart from the first encapsulant and covering the conductive element,
wherein the second electronic component is configured to receive a power from the first conductive element.

19. The electronic device of claim 18, further comprising:
a second encapsulant encapsulating the second electronic component and spaced apart from the first encapsulant; and
an electrical contact within a gap between the first encapsulant and the second encapsulant and electrically connecting the first conductive element and the second electronic component.

20. The electronic device of claim 18, further comprising:
a second conductive element disposed over the first electronic component and electrically connecting the first electronic component and the second electronic component, wherein the first encapsulant has an upper surface substantially coplanar with an upper surface of the first conductive element and the second conductive element.
